(19) United States
(12) Patent Application Publication
(10) Pub. No.: US 2021/0408367 A1
(43) Pub. Date: Dec. 30, 2021

(54) METHOD FOR PRODUCING FERROELECTRIC POLYMER ELEMENT, FERROELECTRIC POLYMER ELEMENT AND PIEZOELECTRIC SENSOR

(71) Applicant: NATIONAL UNIVERSITY CORPORATION YAMAGATA UNIVERSITY, , YAMAGATA-shi (JP)

(72) Inventors: TOMOHITO SEKINE, YONEZAWA-SHI, YAMAGATA (JP); TAKEO SHIBA, YONEZAWA-SHI, YAMAGATA (JP); SHIZUO TOKITO, YONEZAWA-SHI, YAMAGATA (JP)

(21) Appl. No.: 17/267,925

(22) PCT Filed: Dec. 27, 2019
(86) PCT No.: PCT/JP2019/051516

§ 371 Date: Feb. 11, 2021

(30) Foreign Application Priority Data
Feb. 27, 2019 (JP) 2019-034039

(51) Int. Cl. H01L 41/317; G01L 1/16; H01L 41/113; H01L 41/193; H01L 41/43

(52) U.S. Cl. CPC H01L 41/317; G01L 1/16; H01L 41/43; H01L 41/193; H01L 41/1132

(57) ABSTRACT

A method for producing a ferroelectric polymer element includes: disposing one electrode on a substrate; applying polymer solution in which a polyvinylidene fluoride-based polymer is dissolved in a solvent including an aprotic polar solvent onto the one electrode by forme-based printing; firing the polymer solution to crystallize the polyvinylidene fluoride-based polymer, so that a ferroelectric layer is formed; and disposing the other electrode on the ferroelectric layer.

### TECHNICAL FIELD

The present invention relates to a method for producing a ferroelectric polymer element, a ferroelectric polymer element, and a piezoelectric sensor. More specifically, the present invention relates to a method for producing a ferroelectric polymer element using a polyvinylidene fluoride-based polymer, a ferroelectric polymer element, and a piezoelectric sensor.

### BACKGROUND ART

Conventionally, the ferroelectric polymer element using a polyvinylidene fluoride-based polymer has been in practical use. This ferroelectric polymer element is configured by sandwiching a ferroelectric layer of polyvinylidene fluoride-based polymers such as P(VDF-TrFE) between a pair of electrodes. Generally, the ferroelectric layer of the ferroelectric polymer element has a thickness of 10 μm to 100 μm. Therefore, there is a demand to form a thin ferroelectric layer having a thickness of, for example, equal to or smaller than 50 μm.

Thus, as a technology for forming a thin ferroelectric layer, there has been proposed a method of forming a thin film piezoelectric element by using spin coating, which is an easy method to prevent an increase in the thickness of the thin film piezoelectric element at the outer edge of a wafer (so-called “edge bead”), and also prevent occurrence of crack due to the unevenness of the thickness of the edge (see, for example, Patent Literature 1). With this method of forming a thin film piezoelectric element, thin film forming agent is applied by the spin coating, and therefore it is possible to form a thin ferroelectric layer.

### CITATION LIST

### Patent Literature

PTL1: Japanese Patent Application Laid-Open No. 2016-58694

### SUMMARY OF INVENTION

### Technical Problem

However, the method of forming a thin film piezoelectric element disclosed in Patent Literature 1 employs the spin coating to form a ferroelectric layer, which makes it difficult to form a flat layer, compared to forme-based printing such as screen printing.

To solve this conventional problem, it is therefore an object of the invention to provide a method for producing a ferroelectric polymer element which can form a ferroelectric layer flatly, a ferroelectric polymer element, and a piezoelectric sensor.

### Solution to Problem

An aspect of the invention provides a method for producing a ferroelectric polymer element including: disposing one electrode on a substrate; applying polymer solution in which a polyvinylidene fluoride-based polymer is dissolved in a solvent including an aprotic polar solvent onto the one electrode by forme-based printing; firing the polymer solution to crystallize the polyvinylidene fluoride-based polymer, so that a ferroelectric layer is formed; and disposing the other electrode on the ferroelectric layer.

It is preferred that the aprotic polar solvent has a dipole moment equal to or greater than 2.6 D and not greater than 4.2 D.

It is preferred that the polymer solution has a viscosity of equal to or greater than 0.5 Pa·s and not greater than 13.8 Pa·s.

An aspect of the invention provides a ferroelectric polymer element including: a substrate; a pair of electrodes disposed on the substrate; and a ferroelectric layer formed by: applying polymer solution in which a polyvinylidene fluoride-based polymer is dissolved in a solvent including an aprotic polar solvent onto one of the pair of electrodes by forme-based printing; and firing the polymer solution to crystallize the polyvinylidene fluoride-based polymer, so that the polyvinylidene fluoride-based polymer has an average crystallite size equal to or smaller than 12.8 nm.

An aspect of the invention provides a piezoelectric sensor including: the ferroelectric polymer element described above; and a pressure calculation unit connected to a pair of electrodes of the ferroelectric polymer element and configured to calculate a pressure applied to a ferroelectric layer, based on an electric signal received at the pair of electrodes.

### Advantageous Effect

According to the invention, a ferroelectric layer is formed by: applying polymer solution in which a polyvinylidene fluoride-based polymer is dissolved in an aprotic polar solvent onto one electrode by forme-based printing; and firing the polymer solution to crystallize the polyvinylidene fluoride-based polymer, so that a ferroelectric layer is formed. By this means, it is possible to provide a method for producing a ferroelectric polymer element which can form a ferroelectric layer flatly, a ferroelectric polymer element, and a piezoelectric sensor.

### BRIEF DESCRIPTION OF DRAWINGS

FIG. 1 illustrates the configuration of a ferroelectric polymer element according to Embodiment 1 of the invention;

FIGS. 2A-2C illustrate manufacturing the ferroelectric polymer element;

FIG. 3 illustrates the configuration of a piezoelectric sensor according to Embodiment 2 of the invention;

FIG. 4A illustrates a measurement result of the thickness of a ferroelectric layer according to Example 1;

FIG. 4B illustrates a measurement result of the thickness of a ferroelectric layer according to Example 2;

FIG. 4C illustrates a measurement result of the thickness of a ferroelectric layer according to Example 3;

FIG. 4D illustrates a measurement result of the thickness of a ferroelectric layer according to Example 4;

FIG. 4E illustrates a measurement result of the thickness of a ferroelectric layer according to Example 5;

FIG. 4F illustrates a measurement result of the thickness of a ferroelectric layer according to Comparative Example 1;

FIG. 4G illustrates a measurement result of the thickness of a ferroelectric layer according to Comparative Example 2;

FIG. 4H illustrates a measurement result of the thickness of a ferroelectric layer according to Comparative Example 3;

FIG. 5A illustrates an observation result of the aggregation of P(VDF-TrFE) according to Example 1;

FIG. 5B illustrates an observation result of the aggregation of P(VDF-TrFE) according to Example 2;

FIG. 5C illustrates an observation result of the aggregation of P(VDF-TrFE) according to Example 3;

FIG. 5D illustrates an observation result of the aggregation of P(VDF-TrFE) according to Example 4;

FIG. 5E illustrates an observation result of the aggregation of P(VDF-TrFE) according to Example 5;

FIG. 6A illustrates an observation result of the surface of the ferroelectric layer according to Example 1;

FIG. 6B illustrates an observation result of the surface of the ferroelectric layer according to Example 2;

FIG. 6C illustrates an observation result of the surface of the ferroelectric layer according to Example 3;

FIG. 6D illustrates an observation result of the surface of the ferroelectric layer according to Example 4;

FIG. 6E illustrates an observation result of the surface of the ferroelectric layer according to Example 5;

FIG. 7 is a graph illustrating distribution of RMS values for the dipole moment of an aprotic polar solvent;

FIG. 8 is a graph illustrating distribution of average crystallite sizes for the dipole moment of the aprotic polar solvent;

FIG. 9A is a graph illustrating a measurement result of the thickness of a ferroelectric layer according to Example 6;

FIG. 9B is a graph illustrating a measurement result of the thickness of a ferroelectric layer according to Example 7; and

FIG. 9C is a graph illustrating a measurement result of the thickness of a ferroelectric layer according to Example 8.

### DESCRIPTION OF EMBODIMENTS

Hereinafter the embodiments of the invention will be described with reference to the accompanying drawings.

### Embodiment 1

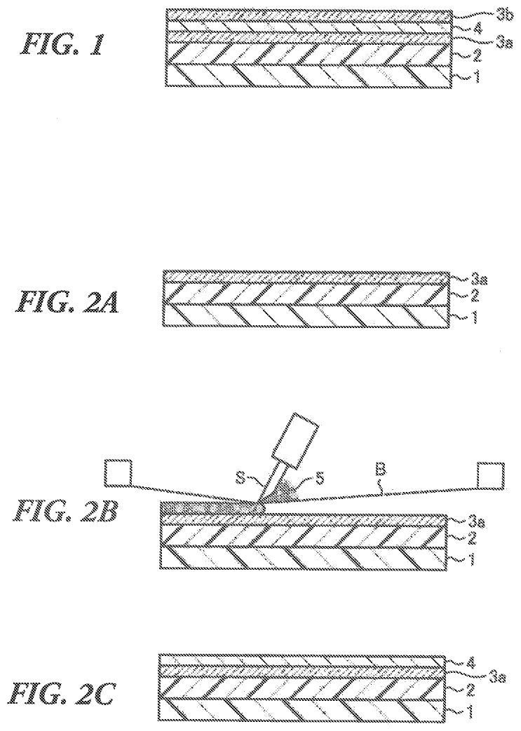

FIG. 1 illustrates the configuration of a ferroelectric polymer element according to Embodiment 1 of the invention. This ferroelectric polymer element includes a substrate 1, a base layer 2 disposed on the surface of the substrate 1, a pair of electrodes 3a and 3b disposed on the surface of the base layer 2, and a ferroelectric layer 4 disposed between the pair of electrodes 3a and 3b.

The substrate 1 is configured to support each part of the ferroelectric polymer element and formed to spread flatly. The substrate 1 may be made of a material having a high rigidity such as glass, or a material having flexibility such as polyethylene naphthalate, polyethylene terephthalate, and polyimide.

The base layer 2 is configured to increase adhesion to the electrode 3a and made of a highly flat material. The base layer 2 may be made of, for example, polyvinylpyrrolidone, and polymethyl methacrylate resin.

The electrodes 3a and 3b are electrically connected to the ferroelectric layer 4, and made of, for example, a conductive material such as a metallic material and an organic conductive material. The metallic material may be, for example, silver and copper. The organic conductive material may be, for example, poly(3,4-Ethylenedioxythiophene):poly(4-styrenesulfonic acid) (PEDOT:PSS). In addition, the electrodes 3a and 3b are formed to have an average thickness of preferably equal to or smaller than 50 μm, and more preferably equal to or smaller than 25 μm. The electrodes 3a and 3b can be formed by printing using a printing plate, such as screen printing, gravure printing, offset printing, and flexographic printing (so-called forme-based printing).

The ferroelectric layer 4 has ferroelectricity, and is made of a material containing a polyvinylidene fluoride-based polymer.

To be more specific, the ferroelectric layer 4 is formed by: applying polymer solution in which a polyvinylidene fluoride-based polymer is dissolved in a solvent including an aprotic polar solvent onto the electrode 3a by the forme-based printing; and firing the polymer solution to crystallize the polyvinylidene fluoride-based polymer, so that the polyvinylidene fluoride-based polymer has an average crystallite size equal to or smaller than 12.8 nm. Here, the ferroelectric layer 4 is formed to have an average thickness of preferably equal to or smaller than 50 μm, and more preferably equal to or smaller than 25 μm. In addition, as the forme-based printing, for example, the screen printing, the gravure printing, the offset printing, and the flexographic printing may be used, in the same way as the electrodes 3a and 3b.

The polyvinylidene fluoride-based polymer may be, for example, a vinylidene fluoridepolymer (PVDF), and a copolymer of vinylidene fluoride and another monomer. The copolymer of vinylidene fluoride and another monomer may be, for example, a poly(vinylidene-trifluoroethylene) copolymer (P(VDF-TrFE)).

The aprotic polar solvent is a polar solvent not containing acid hydrogen, and may be, for example, methyl ethyl ketone (MEK), cyclohexanone (CHN), dimethylsulfoxide (DMSO), dimethylformamide (DMF), and tetramethylpiperidine (TMP).

Here, the aprotic polar solvent has a dipole moment of preferably equal to or greater than 2.6 D and not greater than 4.2 D, and more preferably equal to or greater than 2.6 D and not greater than 3.7 D. Note that multiple types of aprotic polar solvents may be mixed, or an aprotic polar solvent and a protic polar solvent may be mixed to allow the polyvinylidene fluoride-based polymer to be dissolved therein. In this way, when multiple types of polar solvents are mixed, it is preferred that they are mixed such that the overall dipole moment calculated by summing the dipole moment of each of the polar solvents meets the above-described value.

Next, a method for producing the ferroelectric polymer element will be described. First, as illustrated in FIG. 2A, the base layer 2 is applied onto the substrate 1, and then, electrode solution containing PEDOT:PSS is applied onto the base layer 2. The base layer 2 may be applied by, for example, the spin coating. Meanwhile, the electrode solution may be applied by, for example, the screen printing.

The electrode solution applied onto the base layer 2 is fired at about 150 degrees Celsius for 30 minutes to form the electrode 3a having an average thickness of equal to or smaller than about 50 μm on the base layer 2. In this way, the electrode 3a is formed by the forme-based printing, and therefore it is possible to form the electrode 3a having a large dimension. In addition, the electrode 3a is formed on the base layer 2 which is highly flat, and therefore it is possible to improve its adhesion.

Next, as illustrated in FIG. 2B, P(VDF-TrFE) is dissolved in the aprotic polar solvent to prepare polymer solution 5, and then, the polymer solution 5 is applied onto the electrode 3a by the screen printing. To be more specific, a screen plate B with mesh is disposed on the electrode 3a, and the polymer solution 5 is applied onto the upper side of the screen plate B. Then, the polymer solution 5 is pressed on the screen plate B by a squeegee S to apply the polymer solution 5 onto the electrode 3a through the mesh of the screen plate B. In this way, the polymer solution 5 is applied by the screen printing, and therefore it is possible to apply the polymer solution 5 more flatly than, for example, the spin coating. Here, it is preferred that the viscosity of the polymer solution 5 is equal to or greater than 0.5 Pa·s and not greater than 13. 8 Pa·s.

The polymer solution 5 applied onto the electrode 3a in this way is fired at 130 to 140 degrees Celsius for 1 hour to crystallize the P(VDF-TrFE). By this means, as illustrated in FIG. 2C, the ferroelectric layer 4 is formed on the electrode 3a.

Here, the polymer solution 5 used in the forme-based printing such as the screen printing is applied via the mesh, and therefore is limited in various conditions such as viscosity, compared to the solution applied by the spin coating Therefore, even though the conditions of the solution applied by the spin coating are adopted for the forme-based printing, it is difficult to form the ferroelectric layer 4 flatly. For this reason, any method of forming the ferroelectric layer 4 by the forme-based printing has not been established yet. Therefore, according to the invention, P(VDF-TrFE) is dissolved in the aprotic polar solvent, so that the aprotic polar solvent can be rapidly evaporated during the firing. By this means, it is possible to form the surface of the ferroelectric layer 4 flatly. That is, it is possible to form the ferroelectric layer 4 which maintains the flatness obtained when the polymer solution 5 is applied by the screen printing.

To be more specific, the polymer solution 5 in which P(VDF-TrFE) is dissolved in a solvent including an aprotic polar solvent is applied by the forme-based printing, and then fired. By this means, it is possible to reduce the average crystallite size of the P(VDF-TrFE) to a size equal to or smaller than 12.8 nm, and consequently to form the ferroelectric layer 4 having a flat surface with an RMS value equal to or smaller than 45 nm. In addition, by using the aprotic polar solvent having a dipole moment equal to or greater than 2.6 D, it is possible to promote the crystallization of the P(VDF-TrFE), and therefore to improve the electrical characteristic of the ferroelectric layer 4. Meanwhile, by using the aprotic polar solvent having a dipole moment equal to or smaller than 4.2 D, it is possible to rapidly evaporate the aprotic polar solvent during the firing, and therefore to form the surface of the ferroelectric layer 4 more flatly.

In addition, the polymer solution 5 has a viscosity of equal to or greater than 0.5 Pa·s, and therefore it is possible to smoothly aggregate the P(VDF-TrFE). Meanwhile, the polymer solution 5 has a viscosity of equal to or smaller than 13.8 Pa·s, and therefore it is possible to prevent excessive aggregation of the P(VDF-TrFE). By this means, it is possible to form the surface of the ferroelectric layer 4 more flatly. Moreover, the polymer solution 5 is applied by the screen printing, and therefore can be applied over a wider range than, for example, the spin coating, and therefore it is possible to form the ferroelectric layer 4 having a large dimension.

Next, the electrode solution containing PEDOT:PSS is applied onto the ferroelectric layer 4 in the same way as the electrode 3a. The electrode solution may be applied by, for example, the screen printing. The electrode solution applied onto the ferroelectric layer 4 is fired at about 150 degrees Celsius for 30 minutes to form the electrode 3b having an average thickness of equal to or smaller than about 50 μm on the ferroelectric layer 4. In this way, the electrode 3b is formed by the forme-based printing, and therefore it is possible to form the electrode 3b having a large dimension. In this case, the surface of the ferroelectric layer 4 is formed flatly, and therefore it is possible to reliably form the electrode 3b. For example, even though the electrode 3b is thin, there is no part of the ferroelectric layer 4 penetrating the electrode 3b, and therefore it is possible to prevent a current leakage. In addition, the ferroelectric layer 4 is formed flatly, and therefore it is possible to form a hysteresis loop which is even in the direction of its surface, and consequently to generate a uniform voltage between the electrode 3a and the electrode 3b. In this way, as illustrated in FIG. 1, it is possible to manufacture the ferroelectric polymer element having the ferroelectric layer 4 and the electrodes 3a and 3b each having a large dimension and being flat.

According to the present embodiment, the polymer solution in which the polyvinylidene fluoride-based polymer is dissolved in the solvent including an aprotic polar solvent is applied onto the electrode 3a by the forme-based printing. Therefore, it is possible to rapidly evaporate the aprotic polar solvent during the firing to form the ferroelectric layer 4 flatly.

### Embodiment 2

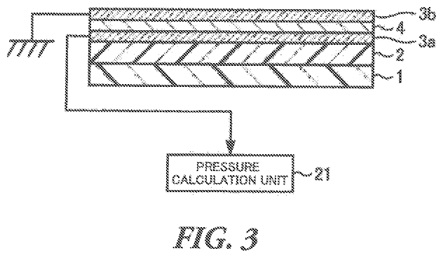

The ferroelectric polymer element according to Embodiment 1 can be used in a piezoelectric sensor configured to detect a pressure. For example, as illustrated in FIG. 3, a pressure calculation unit 21 may be additionally disposed in Embodiment 1.

The pressure calculation unit 21 is electrically connected to the pair of electrodes 3a and 3b of the ferroelectric polymer element. To be more specific, the electrode 3a is connected to the pressure calculation unit 21, and the electrode 3b is grounded. The pressure calculation unit 21 is configured to calculate the pressure applied to the ferroelectric layer 4, based on an electric signal inputted from the electrodes 3a and 3b. With this configuration, the ferroelectric layer 4 generates an electric signal corresponding to the pressure from the outside, and this electric signal is inputted to the pressure calculation unit 21 via the electrodes 3a and 3b. Then, the pressure calculation unit 21 calculates the pressure applied from the outside, based on the electric signal inputted from the electrodes 3a and 3b.

According to the present embodiment, the electrodes 3a and 3b are disposed onto the ferroelectric layer 4 formed flatly. Therefore, it is possible to surely output the electric signal generated by the ferroelectric layer 4, and consequently to accurately calculate the pressure applied to the ferroelectric layer 4 by the pressure calculation unit 21.

Here, with the present embodiment, the ferroelectric polymer element is used in a piezoelectric sensor, but this is by no means limiting as long as the ferroelectricity can be utilized. The ferroelectric polymer element may be used in, for example, an infrared radiation sensor, an ultrasonic transducer, a memory device, and an actuator a Moreover, with the present embodiment, the electrode 3a is connected to the pressure calculation unit 21, and the electrode 3b is grounded, but this is by no means limiting. The electrode 3a may be grounded, and the electrode 3b may be connected to the pressure calculation unit 21.

### EXAMPLES

### Example 1

A polyethylenenaphthalate (PEN) film (QGSHA, produced by Du Pont. Co.jp) having an average thickness of about 50 μm was fixed to a glass carrier haying a length of 100 mm and a width of 100 mm to form the substrate 1. Next, PVP solution in which cross-linked poly(4-vinylphenol) (PVP) (436224, produced by Sigma-Aldrich Japan) was dissolved and melamine resin (418560, produced by Sigma-Aldrich Japan) were dissolved in 1-methoxy-2-propyl acetate (01948-00, produced by KANTO CHEMICAL CO., INC), and this solution was applied onto the PEN film as the substrate 1 by the spin coating to form the base layer 2. PEDOT:PSS (CLAVIOSSV4STAB, produced by Heraeus) was applied onto the base layer 2 by the screen printing (MT320T, produced by Micro-tec Co., Ltd.) and fired at 150 degrees Celsius for 30 minutes to form the electrode 3a having an average thickness of about 500 nm. Next, P(VDF-TrFE) (62-010, produced by Piezotech, mole ratio of VDF:TrEE 75:25) was dissolved in an aprotic polar solvent to prepare the polymer solution 5 containing 10% by weight of P(VDF-TrFE). As the aprotic polar solvent, cyclohexanone (CHN) was used. This polymer solution 5 was applied onto the electrode 3a with an average thickness of about 2 μm by the screen printing, and fired at 130 to 140 degrees Celsius for 1 hour to form the ferroelectric layer 4. Then, the PEDOT:PSS was applied to the ferroelectric layer 4 by the screen printing, and fired at 135 degrees Celsius for 30 minutes to form the electrode 3b having an average thickness of about 500 nm. Fluorine resin (CYTOP®, CTX-809A, produced by AGC) was applied onto the electrode 3b with a thickness of 200 nm by the spin coating, and fired at 100 degrees Celsius for 10 minutes to form a protective layer. By this means, the ferroelectric polymer element was manufactured.

### Example 2

The ferroelectric polymer element was manufactured by the same method as Example 1, except for using methyl ethyl ketone (MEK) as the aprotic polar solvent in which the P(VDF-TrFE) was dissolved.

### Example 3

The ferroelectric polymer element was manufactured by the same method as Example 1, except for using dimethylsulfoxide (DMSO) as the aprotic polar solvent in which the P(VDF-TrFE) was dissolved.

### Example 4

The ferroelectric polymer element was manufactured by the same method as Example 1, except for using dimethylformamide (DMF) as the aprotic polar solvent in which the P(VDF-TrFE) was dissolved. Here, the polymer solution 5 having a viscosity of about 1 Pa·s was used.

### Example 5

The ferroelectric polymer element was manufactured by the same method as Example 1, except for using tetramethylpiperidine (TMP) as the aprotic polar solvent in which the P(VDF-TrFE) was dissolved.

### Example 6

The ferroelectric polymer element was manufactured by the same method as Example 4, except that the viscosity of the polymer solution 5 was 0.5 Pa·s by changing the concentration of the P(VDF-TrFE).

### Example 7

The ferroelectric polymer element was manufactured by the same method as Example 4, except that the viscosity of the polymer solution 5 was 4.70 Pa·s by changing the concentration of the P(VDF-TrFE).

### Example 8

The ferroelectric polymer element was manufactured by the same method as Example 4, except that the viscosity of the polymer solution 5 was 13.8 Pa·s by changing the concentration of the P(VDF-TrFE).

### Comparative Example 1

The ferroelectric polymer element was manufactured by the same method as Example 1, except for using protic polar solvent to dissolve the P(VDF-TrFE) instead of the aprotic polar solvent. Diethylamine was used as the protic polar solvent.

### Comparative Example 2

The ferroelectric polymer element was manufactured by the same method as Example 1, except for using the protic polar solvent to dissolve the P(VDF-TrFE) instead of the aprotic polar solvent. Triethylamine was used as the protic polar solvent.

### Comparative Example 3

The ferroelectric polymer element was manufactured by the same method as Example 1, except that 12% by weight of the P(VDF-TrFE) was dissolved in cyclopentanone as the aprotic polar solvent to prepare the polymer solvent 5, and the polymer solvent 5 was applied onto the electrode 3a by the spin coating. The spin coating was conducted by rotating the substrate 1 at 500 rpm for 60 seconds. Here, the substrate 1 having a length of 20 mm and a width of 25 mm was used.

### <Evaluation Method>

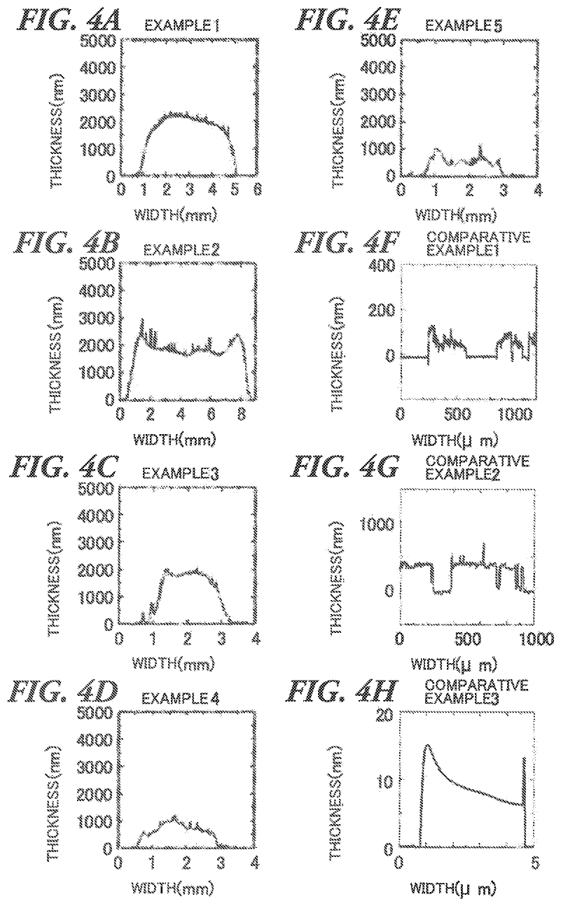

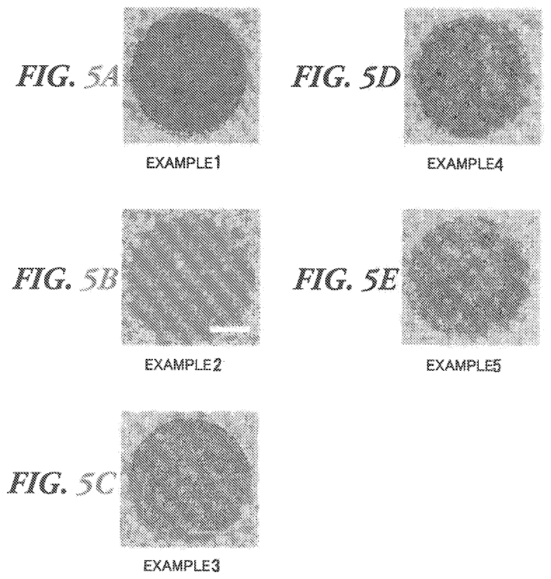

After the step of forming the ferroelectric layer 4 in manufacturing the ferroelectric polymer element, the cross-sectional shape of the ferroelectric layer 4 was observed by an optical microscope to obtain image data, and the thickness of the ferroelectric layer 4 was calculated from the image data. The result is illustrated in FIGS. 4A to 4H. In addition, aggregation of the P(VDF-TrFE) was observed from the image data of the optical microscope. The result is illustrated in FIGS. 5A to 5E.

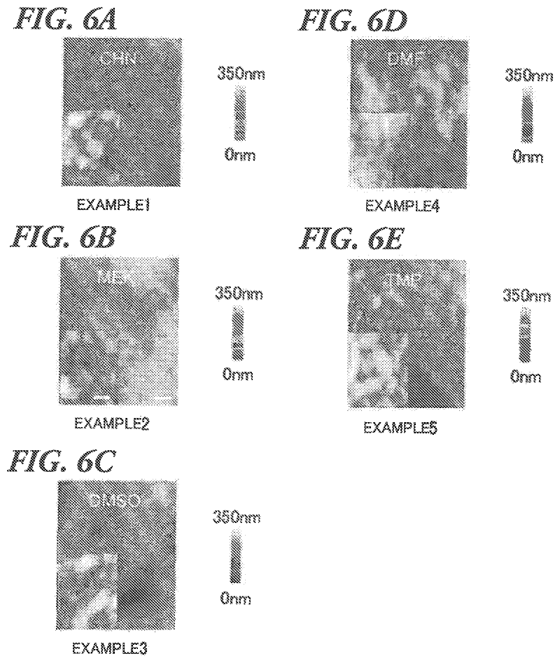

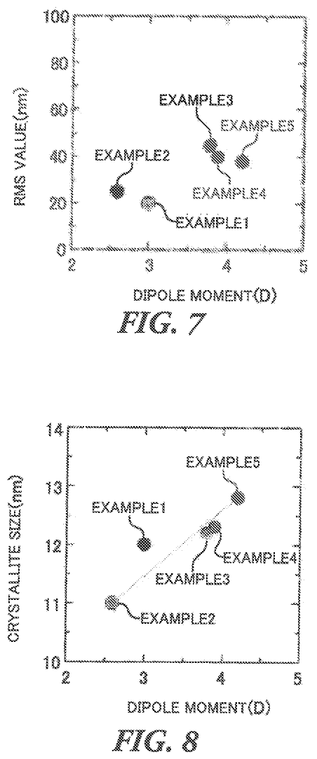

After the step of forming the ferroelectric layer 4 in manufacturing the ferroelectric polymer element, the surface of the ferroelectric layer 4 was observed by an atomic force microscope (5500, produced by Agilent Technologies Japan, Ltd.). The result is illustrated in FIGS. 6A to 6E. In addition, the root-mean-square (RMS) value of the surface of the ferroelectric layer 4 were calculated from the image data of the atomic force microscope, and distribution of the RMS value for the dipole moment of the aprotic polar solvent was obtained. The result is illustrated in FIG. 7. Moreover, the ferroelectric layer 4 was measured by an X-ray diffractometer (SmartLab, produced by Rigaku Corporation) to obtain diffraction data, and the average crystallite size of the ferroelectric layer 4 per unit area was calculated from the diffraction data by using Scherrer equation. Then, distribution of the average crystallite size for the dipole moment of the aprotic polar solvent was obtained. The result is illustrated in FIG. 8.

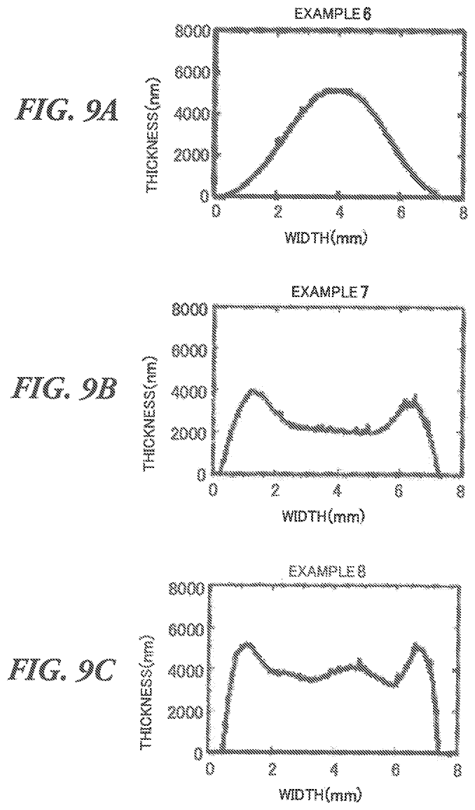

The cross-sectional shape of the ferroelectric layer 4 manufactured with a changed viscosity of the polymer solution 5 was observed by the optical microscope to obtain image data, and the thickness of the ferroelectric layer 4 was calculated from the image data. The result is illustrated in FIGS. 9A to 9C.

From the result illustrated in FIGS. 4A to 4G, it is found that, with Examples 1 to 5 where the P(VDF-TrFE) is dissolved in the aprotic polar solvent, the thickness of the ferroelectric layer 4 was not significantly changed, and meanwhile, with Comparative examples 1 and 2 where the P(VDF-TrFE) is dissolved in the protic polar solvent, the thickness of part of the ferroelectric layer 4 was 0 nm, and the thickness of the ferroelectric layer 4 is significantly changed to such an extent that the base layer is exposed. In addition, it is found that, with Examples 1 to 3 using the aprotic polar solvent having the dipole moment equal to or greater than 2.6 D and not greater than 3.7 D, the thickness is not significantly changed and is not rapidly changed, compared to Examples 4 and 5 using the aprotic polar solvent having the dipole moment equal to or greater than 3.8 D. Moreover, it is found that, with Example 1 using the aprotic polar solvent having the dipole moment of 3.0 D, the thickness is not significantly changed and is not rapidly changed, compared to Example 2 using the aprotic polar solvent having the dipole moment of 2.6 D.

Furthermore, from the result illustrated in FIG. 4H, it is found that, with Comparative example 3 where the polymer solution 5 is applied by the spin coating, the thickness is significantly changed by about 10 μm, compared to Examples 1 to 5 where the polymer solution 5 is applied by the forme-based printing, and therefore it is not possible to forth the ferroelectric layer 4 flatly. Accordingly, if the electrode 3b is applied onto the ferroelectric layer 4 formed by the spin coating, part of the ferroelectric layer 4 may penetrate the electrode 3b and consequently a current leakage may occur. In addition, the hysteresis loop which is even in the direction of the surface of the ferroelectric layer 4 may not be obtained.

From the result illustrated in FIGS. 5A to 5E, it is found that, with Examples 1 to 3 using the aprotic polar solvent having the dipole moment equal to or greater than 2.6 D and not greater than 3.7 D, the P(VDF-TrFE) is not highly aggregated but is diffused over all, compared to Examples 4 and 5 using the aprotic polar solvent having the dipole moment equal to or greater than 3.8 D. Moreover, it is found that, with Example 1 using the aprotic polar solvent having the dipole moment of 3.7 D, the crystallization of the P(VDF-TrFE) is promoted to form crystals in proper size, compared to Example 2 using the aprotic polar solvent having the dipole moment of 2.6 D.

From this, it is found that the polymer solution 5 in which the polyvinylidene fluoride-based polymer is dissolved in the aprotic polar solvent is applied by the forme-based printing, and therefore it is possible to form the ferroelectric layer 4 flatly. In addition, it is found that Example 1 allows the surface of the ferroelectric layer 4 to be formed more flatly with crystals in proper size than Examples 2 to 5, and that Examples 2 and 3 allow the surface of the ferroelectric layer 4 to be formed more flatly than Examples 4 and 5.

From the result illustrated in FIGS. 6A to 6E, it is found that, with Examples 1 to 5, the greater the dipole moment value is, the higher the surface roughness of the ferroelectric layer 4 is. In addition, from the result illustrated o FIG. 7, it is found that, with Examples 1 to 5, the greater the dipole moment value is, the greater the RMS value of the surface of the ferroelectric layer 4 is. Likewise, from the result illustrated in FIG. 8, it is found that, with Examples 1 to 5, the greater the dipole moment value is, the greater the average crystallite size of the ferroelectric layer 4 is. From this, it is suggested that, with Examples 1 to 5, the greater the dipole moment value is, the more the electrical characteristic of the ferroelectric layer 4 is improved in view of the hysteresis loop. In fact, in a case where the residual dielectric polarization value was measured when an alternating current voltage (1 Hz, ±100 MV/m) was applied between the electrodes 3a and 3b of the ferroelectric polymer element manufactured according to Examples 1 to 5, the greater the dipole moment value was, the more the electrical characteristic was improved. Therefore, it is understood that, by using the aprotic polar solvent having the dipole moment equal to or greater than 2.6 D and not greater than 4.2 D, the ferroelectric layer 4 can be formed with crystals in proper size and flattened while keeping its electrical characteristic.

Here, as illustrated in FIG. 8, it is found that, with Examples 1 to 5, the average crystallite size of the ferroelectric layer 4 is small (equal to or smaller than 12.8 nm). From this, it is found that the polymer solution 5 in which the polyvinylidene fluoride-based polymer is dissolved in the solvent including an aprotic polar solvent is applied by the forme-based printing and fired, and therefore it is possible to reduce the average crystallite size of the polyvinylidene fluoride-based polymer to a size equal to or smaller than 12.8 nm, and consequently to flatten the ferroelectric layer 4. To be more specific, the average crystallite size of the ferroelectric layer 4 is 12 nm with Example 1, 11.8 nm with Example 2, 12.2 nm with Example 3, 12.3 nm with Example 4, and 12. 8 nm with Example 5. From this, it is found that Examples 1 to 4 using the aprotic polar solvent having the dipole moment equal to or greater than 2.6 D and not greater than 3.9 D allow the average crystallite size of the ferroelectric layer 4 to be smaller than Example 5 using the aprotic polar solvent having the dipole moment of 4.2 D. In addition, it is found that Examples 1 and 2 using the aprotic polar solvent having the dipole moment equal to or greater than 2.6 D and not greater than 3.0 D allow the average crystallite size of the ferroelectric layer 4 to be smaller than. Examples 3 and 4 using the aprotic polar solvent having the dipole moment equal to or greater than 3.8 D, and that Example 2 using the aprotic polar solvent having the dipole moment of 2.6D allows the average crystallite size of the ferroelectric layer 4 to be minimized.

Moreover, as illustrated in FIG. 7, it is found that Examples 1 to 5 allow the ferroelectric layer 4 to be formed with a flat surface at an RMS value equal to or smaller than 45 nm. From this, it is found that the polymer solution 5 in which the polyvinylidene fluoride-based polymer is dissolved in the solvent including an aprotic polar solvent is applied by the forme-based printing and fired, and therefore it is possible to form the ferroelectric layer 4 having a flat surface with an RMS value equal to or smaller than 45 nm. To be more specific, the RMS value of the ferroelectric layer 4 is 20 nm with Example 1, 25 nm with Example 2, 45 nm with Example 3, 40 nm with Example 4, and 38 nm with Example 5. From this, it is found that Examples 1 and 2 using the aprotic polar solvent having the dipole moment equal to or greater than 2.6 D and not greater than 3.0 D allow the RMS value of the ferroelectric layer 4 to be smaller than Examples 3 to 5 using the aprotic polar solvent having the dipole moment equal to or greater than 3.8 D and not greater than 4.2 D.

From the result illustrated in FIG. 9, it is found that, with Example 7 where the polymer solution 5 having a viscosity of 4.70 Pa·s is applied, the thickness of the ferroelectric layer 4 is not more significantly changed and the ferroelectric layer 4 is formed more flatly, than Examples 6 and 8 where the polymer solution 5 having a viscosity of 0.5 Pa·s and the polymer solution 5 having a viscosity of 13.8 Pa·s are applied. Here, with Examples 6 to 8, when the surface of the ferroelectric layer 4 was observed by the atomic force microscope, there was not a significant difference in the surface roughness among them. From this, it is suggested that the viscosity of the polymer solution 5 does not contribute to microscopic flattening such as the crystallite size, but contributes to macroscopic flattening of the ferroelectric layer 4.

### REFERENCE SIGNS LIST

1 substrate, 2 base layer, 3a and 3b electrode, 4 ferroelectric layer, 5 polymer solution, B screen plate, S squeegee.

1. A method for producing a ferroelectric polymer element, comprising:
disposing one electrode on a substrate;
applying polymer solution in which a polyvinylidene fluoride-based polymer is dissolved in a solvent including an aprotic polar solvent onto the one electrode by forme-based printing;
firing the polymer solution to crystallize the polyvinylidene fluoride-based polymer, so that a ferroelectric layer is formed; and
disposing the other electrode on the ferroelectric layer.

2. The method for producing a ferroelectric polymer element according to claim 1, wherein the aprotic polar solvent has a dipole moment equal to or greater than 2.6 D and not greater than 4.2 D.

3. The method for producing a ferroelectric polymer element according to claim 1, wherein the polymer solution has a viscosity of equal to or greater than 0.5 Pa·s and not greater than 13.8 Pa·s.

4. A ferroelectric polymer element comprising:
a substrate;
a pair of electrodes disposed on the substrate; and
a ferroelectric layer formed by:
applying polymer solution in which a polyvinylidene fluoride-based polymer is dissolved in a solvent including an aprotic polar solvent onto one of the pair of electrodes by forme-based printing; and
firing the polymer solution to crystallize the polyvinylidene fluoride-based polymer, so that the polyvinylidene fluoride-based polymer has an average crystallite size equal to or smaller than 12.8 nm.

5. A piezoelectric sensor comprising:
a ferroelectric polymer element according to claim 4; and
a pressure calculation unit connected to a pair of electrodes of the ferroelectric polymer element and configured to calculate a pressure applied to a ferroelectric layer, based on an electric signal received at the pair of electrodes.
